(19) United States
(12) Patent Application Publication
(10) Pub. No.: US 2014/0284308 A1
(43) Pub. Date: Sep. 25, 2014

(54) PLASMA ETCHING METHOD AND PLASMA ETCHING APPARATUS

(71) Applicants: KABUSHIKI KAISHA TOSHIBA, Minato-ku (JP); TOKYO ELECTRON LIMITED, Minato-ku (JP)

(72) Inventors: Shoichiro MATSUYAMA, Kurogkawa-gun (JP); Akitaka SHIMIZU, Nirasaki-shi (JP); Susumu NOGAMI, Kurogkawa-gun (JP); Kiyohito ITO, Hopewell Junction, NY (US); Tokuhisa OHIWA, Kawasaki-shi (JP); Katsunori YAHASHI, Yokkaichi-shi (JP)

(73) Assignees: KABUSHIKI KAISHA TOSHIBA, Minato-ku (JP); TOKYO ELECTRON LIMITED, Minato-ku (JP)

(21) Appl. No.: 14/219,437

(22) Filed: Mar. 19, 2014

(30) Foreign Application Priority Data
Mar. 25, 2013 (JP) 2013-061361

(51) Int. Cl. H01J 37/32

(52) U.S. Cl. CPC H01J 37/32045
USPC 216/67; 156/345.44

(57) ABSTRACT

There are provided a plasma etching method and a plasma etching apparatus, capable of suppressing occurrence of local bias in etching rate and suppressing occurrence of charge-up damage. The plasma etching method of etching a silicon layer of a substrate to be processed using the plasma etching apparatus sets the pressure in a processing chamber to 13.3 Pa or more and applies, to a lower electrode, a first high-frequency power with a first frequency and a second high-frequency power with a second frequency that is lower than the first frequency and is a frequency of 1 MHz or lower.

### CROSS-REFERENCE TO RELATED APPLICATION

This application is based upon and claims the benefit of priority from the prior Japanese Patent Application No. 2013-061361, filed on Mar. 25, 2013; the entire contents of all of which are incorporated therein by reference.

### FIELD

Embodiments described herein relate generally to a plasma etching method and a plasma etching apparatus.

### BACKGROUND

Conventionally, plasma etching of making an etching gas into plasma and causing it to act on a substrate (semiconductor wafer) to be processed to thereby etch a silicon layer or the like on the substrate to be processed is used in a manufacturing process of a semiconductor device. In this plasma etching, electric charges accumulate on a part of the substrate to be processed and discharge (arcing) occurs to cause a so-called charge-up damage such as occurrence of dielectric breakdown and so on in some cases. A technology to suppress the occurrence of the charge-up damage has been conventionally developed.

### BRIEF DESCRIPTION OF THE DRAWINGS

FIG. 1 is a view schematically illustrating a rough structure of a plasma etching apparatus according to a first embodiment.

FIG. 2 is a view schematically illustrating a rough structure of a plasma etching apparatus according to a second embodiment.

FIG. 3 is a view explaining a method of evaluating charge-up damage.

FIG. 4 is a graph indicating the relationship between Vdc and the electron density in the cases of frequencies of 100 MHz and 40 MHz.

FIG. 5A is a chart indicating an example of an in-plane distribution of the etching rate in the prior art, and FIG. 5B is a chart indicating an example of an in-plane distribution of the etching rate in the embodiment.

### DETAILED DESCRIPTION

As a method of obtaining a high etching rate in silicon etching, a general method performs plasma etching in a plasma state with many radicals. Further, in such plasma etching, it is performed to cover an opposed surface, of a counter electrode (upper electrode), opposed to the substrate to be processed with a quartz member or the like in order to reduce metallic contamination of the devices on the substrate to be processed.

However, if a dielectric is arranged on the upper electrode as described above, the effective anode/cathode area ratio decreases to reduce a self-bias voltage (Vdc) applied to the substrate to be processed. For this reason, the sheath located directly on the substrate to be processed becomes thinner, so that electrons in the plasma become likely to leap the sheath to enter the substrate to be processed. Therefore, the substrate to be processed becomes susceptible to uneven distribution of plasma, thus frequently leading to a case where local bias in etching rate such that the etching rate at a center portion of the substrate to be processed is locally high or the like, and a case where charge-up damage occurs.

Further, in the plasma etching apparatus, it is desired to drive the upper electrode provided on an upper ceiling plate of a vacuum processing container to control the gap (process gap) with respect to the lower electrode provided at a lower part of the vacuum processing container in order to improve the process performance. Generally, for a drive mechanism part driving the upper electrode, a bellows is used as a sealing material made of a metal material shielding vacuum from atmospheric air. In this case, the impedance between the ground of the vacuum processing container and the whole upper ceiling plate including the upper electrode tends to increase. Therefore, the effective anode/cathode area ratio further decreases to cause a problem of inducing further local bias in etching rate and charge-up damage.

In the manufacturing process of the semiconductor device in recent years, it becomes necessary to improve the process performance such as optimization of process conditions and so on in an apparatus configuration which is likely to induce the above-described charge-up damage.

An embodiment described below has been made to cope with the above circumstances, and its object is to provide a plasma etching method and a plasma etching apparatus, capable of suppressing occurrence of local bias in etching rate and suppressing occurrence of charge-up damage.

An aspect of the plasma etching method according to an embodiment is a plasma etching method of etching a silicon layer of a substrate to be processed using a plasma etching apparatus, the plasma etching apparatus including: a processing chamber which houses the substrate to be processed; a lower electrode which is arranged in the processing chamber and on which the substrate to be processed is mounted; an upper electrode which is arranged in the processing chamber and opposed to the lower electrode; an etching gas supply mechanism which supplies a predetermined etching gas into the processing chamber; and an exhaust mechanism which exhausts gas from the processing chamber, the plasma etching method including: setting a pressure in the processing chamber to 13.3 Pa or more; and applying, to the lower electrode, a first high-frequency power with a first frequency and a second high-frequency power with a second frequency that is lower than the first frequency and is a frequency of 1 MHz or lower.

An aspect of the plasma etching apparatus according to an embodiment etches a silicon layer of a substrate to be processed and includes: a processing chamber which houses the substrate to be processed; a lower electrode which is arranged in the processing chamber and on which the substrate to be processed is mounted; an upper electrode which is arranged in the processing chamber and opposed to the lower electrode; an etching gas supply mechanism which supplies a predetermined etching gas into the processing chamber; an exhaust mechanism which exhausts gas from the processing chamber; a first high-frequency power supply which applies a first high-frequency power with a frequency of 80 MHz or higher and 150 MHz or lower to the lower electrode; and a second high-frequency power supply which applies a second high-frequency power with a frequency of 1 MHz or lower to the lower electrode.

According to the embodiment, a plasma etching method and a plasma etching apparatus, capable of suppressing occurrence of local bias in etching rate and suppressing occurrence of charge-up damage can be provided.

### First Embodiment

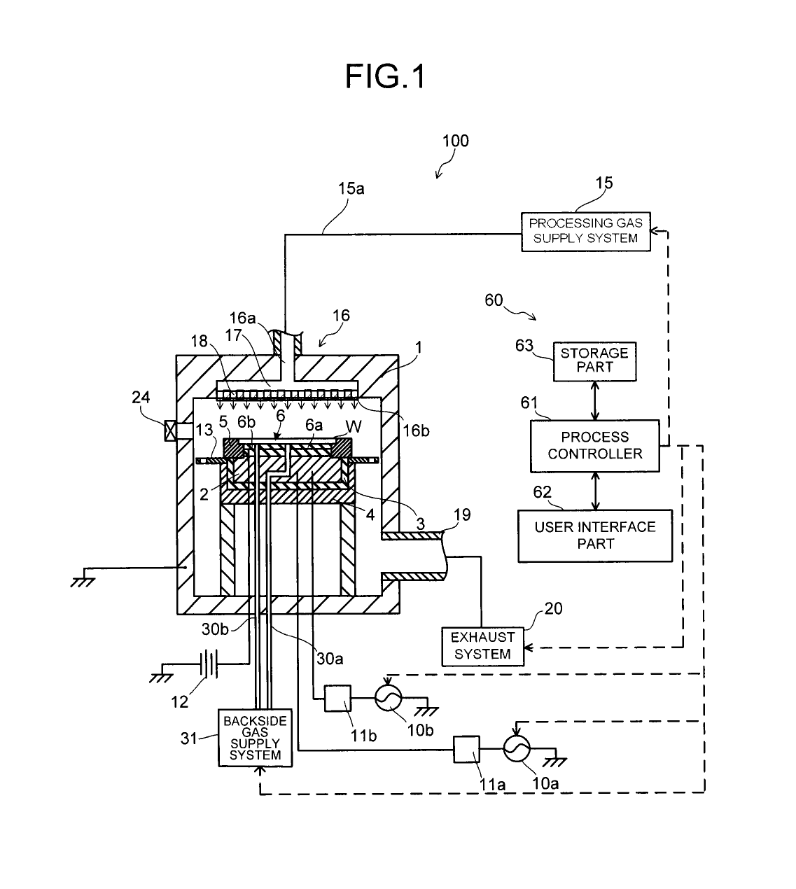

Hereinafter, embodiments will be described referring to the drawings. FIG. 1 is a view schematically illustrating a rough structure of a plasma etching apparatus according to a first embodiment. A plasma etching apparatus 100 illustrated in FIG. 1 has a processing chamber 1 that is hermetically structured and electrically connected to the ground potential.

The processing chamber 1 is formed in a cylindrical shape and made of, for example, aluminum or the like having an anodic oxide coating formed on the surface. In the processing chamber 1, a mounting table 2 is provided on which a semiconductor wafer W being a substrate to be processed is substantially horizontally mounted. The mounting table 2 serves also as a lower electrode, and is composed of a conductive material such as aluminum or the like and supported on a support table 4 being a conductor via an insulating plate 3. Further, at an outer peripheral portion on the mounting table 2, a focus ring 5 formed in a ring shape made of SiC or the like is provided in a manner to surround the periphery of the semiconductor wafer W.

To the mounting table 2, a first high-frequency power supply 10a is connected via a first matching box 11 a and a second high-frequency power supply 10b is connected via a second matching box 11b. From the first high-frequency power supply 10a, high-frequency power with a frequency of, for example, 80 MHz to 150 MHz (100 MHz in this embodiment) is supplied to the mounting table 2. Meanwhile, from the second high-frequency power supply 10b, high-frequency power with a frequency that is lower than that from the first high-frequency power supply 10a and is 1 MHz or lower (0.4 MHz in this embodiment) is supplied to the mounting table 2.

On the other hand, at a position opposed to and above the mounting table 2, a shower head 16 is provided to be in parallel with and opposed to the mounting table 2. This shower head 16 is set at the ground potential. Accordingly, the shower head 16 and the mounting table 2 function as a pair of counter electrodes (upper electrode and lower electrode).

On the upper surface of the mounting table 2, an electrostatic chuck 6 for electrostatically attracting the semiconductor wafer W thereto is provided. The electrostatic chuck 6 is structured such that an electrode 6a intervenes between insulators 6b and a direct-current power supply 12 is connected to the electrode 6a. By applying a direct-current voltage from the direct-current power supply 12 to the electrode 6a, the semiconductor wafer W is attracted by the Coulomb force or the like.

Inside the mounting table 2, a not-illustrated refrigerant flow path is formed so that an appropriate refrigerant is circulated therein to be able to control its temperature. To the mounting table 2, backside gas supply pipes 30a, 30b for supplying a backside gas (back surface side heat transfer gas) such as a helium gas or the like to the back surface side of the semiconductor wafer W are connected to be able to supply the backside gas to the back surface side of the semiconductor wafer W from a backside gas supply source 31. Note that the backside gas supply pipe 30a is for supplying the backside gas to a center portion of the semiconductor wafer W and the backside gas supply pipe 30b is for supplying the backside gas to a peripheral portion of the semiconductor wafer W. This structure make it possible to control the semiconductor wafer W to a predetermined temperature. Further, an exhaust ring 13 is provided below the outside of the focus ring 5. The exhaust ring 13 communicates with the processing chamber 1 via the support table 4.

The shower head 16 provided at a ceiling wall portion of the processing chamber 1 in a manner to be opposed to the mounting table 2 has many gas discharge holes 18 provided in its lower surface and has a gas introduction part 16a provided at its upper portion. Further, a space 17 is formed in the shower head 16. To the gas introduction part 16a, a gas supply pipe 15a is connected, and a processing gas supply system 15 that supplies a processing gas (etching gas) for plasma etching or the like is connected to the other end of the gas supply pipe 15a. Note that a quartz member 16b is arranged on the shower head 16 in a manner to cover its surface opposed to the mounting table 2.

The gas supplied from the processing gas supply system 15 reaches the space 17 inside the shower head 16 via the gas supply pipe 15a and the gas introduction part 16a, and is discharge from the gas discharge holes 18 toward the semiconductor wafer W.

At a lower portion of the processing chamber 1, an exhaust port 19 is formed, and an exhaust system 20 is connected to the exhaust port 19. By operating a vacuum pump provided in the exhaust system 20, the pressure in the processing chamber 1 can be reduced down to a predetermined degree of vacuum. Meanwhile, a gate valve 24 that opens/closes a transfer-in/out port for the semiconductor wafer W is provided in a side wall of the processing chamber 1.

The plasma etching apparatus 100 with the above structure is collectively controlled in operation by a control unit 60. The control unit 60 includes a process controller 61 including a CPU to control the parts in the plasma etching apparatus 100, a user interface part 62, and a storage part 63.

The user interface part 62 is composed of a keyboard for a process manager to perform an input operation of a command to manage the plasma etching apparatus 100, a display that visualizes and displays the operation status of the plasma etching apparatus 100 and so on.

The storage part 63 stores a control program (software) for realizing various kinds of processing executed in the plasma etching apparatus 100 by the control of the process controller 61 and recipes in which processing condition data and the like are stored. Then, an arbitrary recipe is called as necessary from the storage part 63 by an instruction or the like from the user interface part 62 and executed by the process controller 61, whereby desired processing in the plasma etching apparatus 100 is performed under control of the process controller 61. Further, as the control program and the recipe of the processing condition data and the like, those stored in a computer readable computer storage medium (for example, hard disk, CD, flexible disk, semiconductor memory or the like) may be used or those transmitted on demand from another apparatus via, for example, a dedicated line can be used online.

Next, a procedure of plasma-etching the semiconductor wafer W in the plasma etching apparatus 100 with the above structure will be described. First, the gate valve 24 is opened, a semiconductor wafer W is transferred by a not-illustrated transfer robot into the processing chamber 1 via a not-illustrated load lock chamber, and mounted on the mounting table 2. Thereafter, the transfer robot is retracted to the outside of the processing chamber 1, and the gate valve 24 is closed. Then, gas in the processing chamber 1 is exhausted via the exhaust port 19 by the vacuum pump of the exhaust system 20.

After the predetermined degree of vacuum in the processing chamber is reached, a predetermined etching gas is introduced into the processing chamber 1 from the gas supply system 15 to keep the pressure inside the processing chamber 1 at a predetermined pressure, for example, 13.3 Pa (100 mTorr) or more and, in this state, the high-frequency powers are supplied to the mounting table 2 from the first high-frequency power supply 10a and the second high-frequency power supply 10b. In this event, a predetermined direct-current voltage is applied from the direct-current power supply 12 to the electrode 6a of the electrostatic chuck 6, so that the semiconductor wafer W is attracted to the electrostatic chuck 6 by the Coulomb force or the like.

In this case, by applying the high-frequency powers to the mounting table 2 being the lower electrode as described above, an electric field is formed between the shower head 16 being the upper electrode and the mounting table 2 being the lower electrode. This causes discharge in the processing space where the semiconductor wafer W exists, and predetermined plasma etching is performed on the semiconductor wafer W with an etching gas made into plasma by the discharge.

Then, after the predetermined plasma etching ends, the supply of the high-frequency powers and the supply of the etching gas are stopped, and the semiconductor wafer W is transferred out of the processing chamber 1 in an opposite procedure to the above-described procedure.

### Second Embodiment

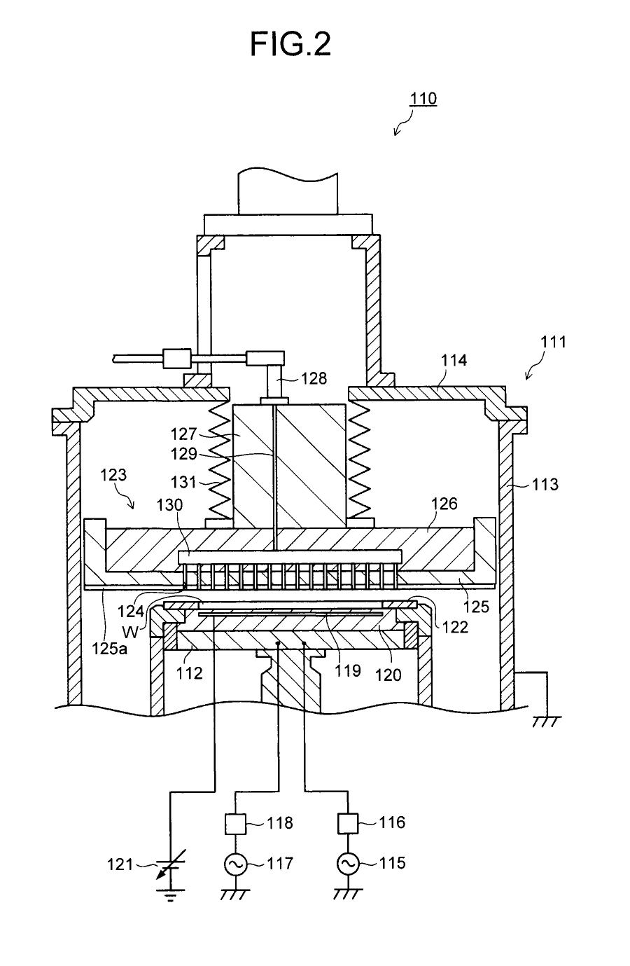

Next, a plasma etching apparatus 110 according to a second embodiment will be described referring to FIG. 2. The plasma etching apparatus 110 illustrated in FIG. 2 has a cylindrical processing chamber 111 (cylindrical container) that houses, for example, a wafer W with a diameter of 300 mm, and a mounting table 112 in a disk shape on which a semiconductor wafer W is mounted is provided at a lower part inside the processing chamber 111. The processing chamber 111 has a cylindrical tubular side wall 113 and a disk-shaped lid 114 that covers the upper end portion of the side wall 113.

To the processing chamber 111, a not-illustrated exhaust mechanism such as TMP (Turbo Molecular Pump), DP (Dry Pump) or the like is connected to be able to keep the pressure in the processing chamber 111 at a predetermined reduced pressure atmosphere.

To the mounting table 112, a first high-frequency power supply 115 is connected via a first matching device 116 and a second high-frequency power supply 117 is connected via a second matching device 118. The first high-frequency power supply 115 applies a relatively high frequency for plasma generation of, for example, 80 MHz or higher and 150 MHz or lower (100 MHz in this embodiment) to the mounting table 112. Further, the second high-frequency power supply 117 applies a bias power with a frequency that is lower than that of the first high-frequency power supply 115 to the mounting table 112. In this embodiment, the frequency of the high-frequency power of the second high-frequency power supply 117 is set to be 1 MHz or lower, for example, 0.4 MHz.

At the top of the mounting table 112, an electrostatic chuck 120 including an electrode plate 119 therein is arranged. The electrostatic chuck 120 is composed of a disk-shaped ceramic member, and a direct-current power supply 121 is connected to the electrode plate 119. When a positive direct-current voltage is applied to the electrode plate 119, a negative potential is generated on a surface (back surface) of the semiconductor wafer W on the electrostatic chuck 120 side to cause an electric field between the electrode plate 119 and the back surface of the wafer W, so that the semiconductor wafer W is attracted and held on the electrostatic chuck 120 by the Coulomb force or the like due to the electric field.

Further, on the mounting table 112, a focus ring 122 is mounted in a manner to surround the periphery of the semiconductor wafer W attracted and held thereon. The focus ring 122 is made of, for example, SiC or the like.

At an upper position inside the processing chamber 111, a shower head 123 (moving electrode) is arranged in a manner to be opposed to the mounting table 112. The shower head 123 has a disk-shaped conductive upper electrode plate 125 having many gas holes 124, a cooling plate 126 that detachably suspends the upper electrode plate 125, a shaft 127 that further suspends the cooling plate 126, and a processing gas receiving part 128 that is arranged at the upper end of the shaft 127. The shower head 123 is grounded via the lid 114 and the side wall 113 and functions as a ground electrode with respect to plasma generation power to be applied to the processing chamber 111. Note that a quartz member 125a is arranged on the upper electrode plate 125 in a manner to cover its surface opposed to the mounting table 112.

The shaft 127 has a gas flow path 129 penetrating the inside thereof in the longitudinal direction, and the cooling plate 126 has a buffer chamber 130 therein. The gas flow path 129 connects the processing gas receiving part 128 and the buffer chamber 130, and each of the gas holes 124 links the buffer chamber 130 with the inside of the processing chamber 111. In the shower head 123, the gas holes 124, the processing gas receiving part 128, the gas flow path 129, and the buffer chamber 130 constitute a processing gas introduction system, and the processing gas introduction system introduces processing gas (etching gas) supplied to the processing gas receiving part 128, into a processing space existing between the shower head 123 and the mounting table 112 inside the processing chamber 111.

Since the outer diameter of the upper electrode plate 125 of the shower head 123 is set to be slightly smaller than the inner diameter of the processing chamber 111, the shower head 123 never comes into contact with the side wall 113. In other words, the shower head 123 is arranged in a manner to loosely fit in the processing chamber 111. Further, the shaft 127 penetrates the lid 114, and the upper portion of the shaft 127 is connected to a lift mechanism (not illustrated) arrange above the plasma etching apparatus 110. The lift mechanism moves the shaft 127 in the longitudinal direction in the drawing and, in this event, the shower head 123 vertically moves like a piston along the center axis of the processing chamber 111 inside the processing chamber 111. This makes it possible to adjust the gap that is the distance of the processing space existing between the shower head 123 and the mounting table 112. Note that the maximum value of the movement amount of the shower head 123 regarding the longitudinal direction in the drawing is, for example, about 70 mm.

A bellows 131 is, for example, a pressure bulkhead made of stainless steel and capable of expansion and contraction, and has one end connected to the lid 114 and the other end connected to the shower head 123. The bellows 131 has a sealing function of shielding the inside of the processing chamber 111 from the outside of the processing chamber 111.

In the plasma etching apparatus 110, the etching gas supplied to the processing gas receiving part 128 is introduced into the processing space via the processing gas introduction system. The introduced etching gas is excited by the plasma generation power applied to the processing space and becomes plasma. Positive ions in the plasma are drawn toward the semiconductor wafer W mounted on the mounting table 112 by the negative bias potential due to the bias power applied to the mounting table 112, and perform etching processing on the semiconductor wafer W.

The operations of the components of the above-described plasma etching apparatus 110, for example, the first high-frequency power supply 115 and the second high-frequency power supply 117, are controlled by a CPU of a control unit (not illustrated) included in the plasma etching apparatus 110 according to a program corresponding to the etching processing.

Here, since the shower head 123 is not in contact with the side wall 113 in the plasma etching apparatus 110, the high-frequency current due to the plasma generation power applied to the processing space flows through the shower head 123, then flows through the bellows 131, the lid 114, and the side wall 113 and reaches the ground. The impedance (mainly an inductance (L) component) of the bellows 113 is large, so that a potential difference is generated between the shower head 123 and the lid 114.

As a method of obtaining a high etching rate in etching mainly by radical etching in the case of plasma-etching a silicon layer of the semiconductor wafer W in the above-described plasma etching apparatus 100 and plasma etching apparatus 110, there is a method of increasing the pressure to a high pressure (for example, 13.3 Pa (100 mTorr) or more) and performing plasma etching in a high halogen partial pressure region. In this case, use of 100 MHz as the frequency of the first high-frequency power and 13 MHz as the frequency of the second high-frequency frequently causes a case of generating local bias in etching rate such that the etching rate becomes higher at the center portion of the semiconductor wafer or charge-up damage occurs.

Further, to reduce metal contamination to devices, the quartz member 16b and the quartz member 125a are used for the counter electrodes (upper electrodes) opposed to the semiconductor wafer W. Therefore, an effective anode/cathode area ratio tends to decrease so that Vdc applied to the semiconductor wafer W becomes smaller. When the Vdc becomes smaller, the sheath located directly on the semiconductor wafer W also becomes thinner, so that electrons in the plasma become likely to leap the sheath to enter the semiconductor wafer W. Therefore, the state of the etching processing on the semiconductor wafer W becomes susceptible to uneven distribution of plasma. Further, it is also generally known that the sheath becomes thinner in the case of performing plasma etching under a high pressure condition and a case of performing etching under the condition that many negative ions are generated such as a case of using gas containing a halogen element.

Further, in the structure in which the upper electrode can be driven to change the process gap (gap between the upper electrode and the lower electrode) as in the plasma etching apparatus 110, the impedance (L component) between the upper unit and the ground is increased by using the bellows 131 at the drive mechanism part as has been described, so that the effective anode/cathode area ratio further decreases and, as a result, becomes more likely to induce local bias in etching rate and charge-up damage.

If conventionally used 13 MHz, 3 MHz or the like is used as the frequency of the second high-frequency power, the positive ions and negative ions having large mass cannot follow the cycle of the second high-frequency power, so that only the positive ions are transported to the semiconductor wafer mainly by steadily formed Vdc. On the other hand, if 1 MHz or lower, for example, 0.4 MHz is used as the frequency of the second high-frequency power as in this embodiment, even the ions having large mass can follow the cycle of the second high-frequency power, so that the positive ions are transported during a time zone when the potential of the semiconductor wafer seen from plasma is negative, whereas the negative ions are transported to the wafer during a time zone when the potential of the semiconductor wafer seen from plasma is positive. This seems to increase disappearance of negative ions to decrease the ratio of the negative ions with respect to electrons, thereby increasing Vdc.

Thus, a thick sheath is formed to be able to inhibit electrons from leaping the sheath to enter the semiconductor wafer, with the result that no conspicuous potential difference occurs within the semiconductor wafer. As a result, it becomes possible to suppress occurrence of local bias in etching rate and charge-up damage.

Further, in the plasma etching under the above condition, it is desirable to realize a higher electron density with a lower power, and therefore the frequency of the first high-frequency power is preferably 80 MHz to 150 MHz, and more preferably 100 MHz.

It is desirable to set the frequency of the first high-frequency power to 80 MHz to 150 MHz as described above also from the following view point. Namely, a so-called waferless cleaning, in which plasma is generated in the processing chamber without transferring the semiconductor wafer into the processing chamber to remove accretion adhering to the processing chamber inner wall, is performed in recent years from the viewpoint of improvement in productivity. What is important in this event is consumption of the mounting table, and it is desirable that the energy of ions entering the mounting table is low. To obtain an accretion removing process with low damage, it is desirable to generate plasma at a high frequency where Vdc is low and a high electron density (high radical density) can be achieved. To this end, it is necessary to set the frequency of the first high-frequency power to 80 MHz or higher.

A graph in FIG. 4 indicates the relationship between the electron density and Vdc in the case of the frequency of the first high-frequency power set to 100 MHz and the case of 40 MHz, where the vertical axis indicates the electron density and the horizontal axis indicates Vdc. As indicated in this graph, in the case of achieving the same plasma density, Vdc can be decreased by increasing the frequency of the first high-frequency power. On the other hand, if the frequency of the first high-frequency power is too high, the uniformity of the etching rate deteriorates, and therefore it is not preferable to set the frequency of the first high-frequency power to a frequency higher than 150 MHz. Accordingly, a frequency in a band of 80 MHz to 150 MHz selected as the frequency of the first high-frequency power can satisfy the requirements of efficient plasma generation, removal of accretion on the processing chamber inner wall with less consumption of the mounting table, and uniformity in etching rate.

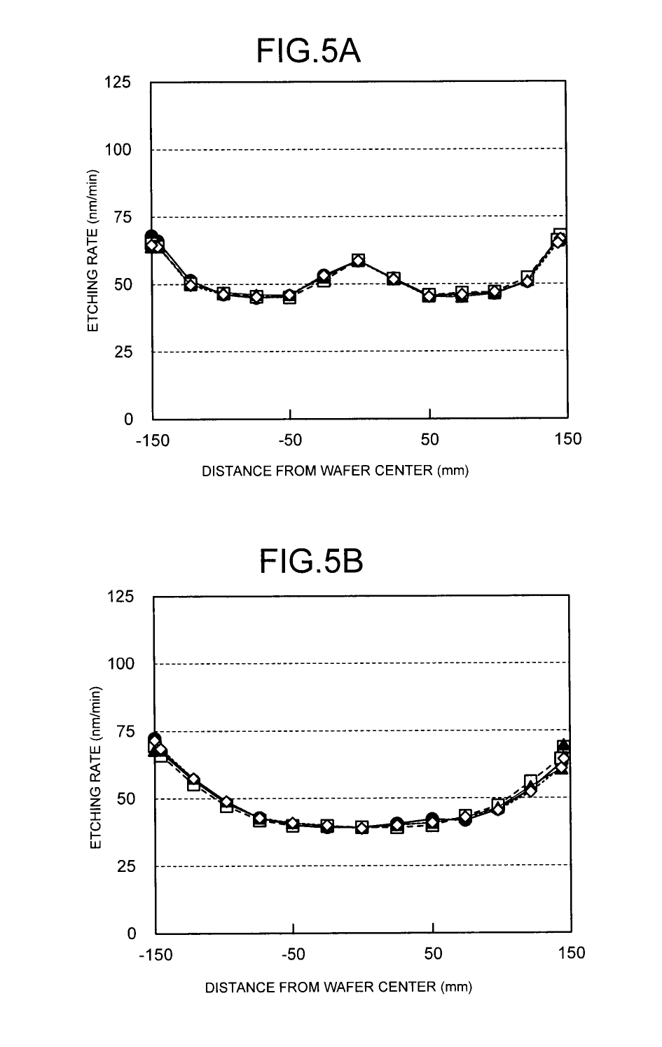

Note that in the case of performing plasma etching on silicon with the frequency of the first high-frequency power set to a high frequency of about 100 MHz and the frequency of the second high-frequency power set to 13 MHz, if the pressure is increased to increase the etching rate, the etching rate tends to become high at the center portion of the semiconductor wafer. The reason can be considered that in the etching under the condition of a high pressure and many negative ions, the negative ions and positive ions accompanying them generally tend to stay at the center portion of the semiconductor wafer and the etching rate therefore increases at the center portion of the semiconductor wafer. An example of an in-plane distribution of the etching rate when plasma etching was performed with the frequency of the first high-frequency power set to 100 MHz, the frequency of the second high-frequency power set to 13 MHz, and the pressure set to 20.0 Pa (150 mTorr) is indicated in a graph in FIG. 5A. As indicated in this graph, the etching rate at the center portion of the semiconductor wafer is locally high.

On the other hand, according to the above-described embodiment, since the frequency of the second high-frequency power is set to be 1 MHz or lower (0.4 MHz) that is the frequency that even the ions having large mass can follow, the negative ions are transported to the semiconductor wafer during the time zone when the potential of the semiconductor wafer seen from plasma is positive. This increases disappearance of negative ions to decrease the ratio of the negative ions with respect to electrons. This eliminates a state that the positive ions tend to stay at the center portion, even if the frequency of the first high-frequency power is set to 100 MHz. As a result, an increase in etching rate at the center portion of the semiconductor wafer is suppressed. An example of an in-plane distribution of the etching rate of an oxide film when plasma etching is performed with the frequency of the first high-frequency power set to 100 MHz, the frequency of the second high-frequency power set to 0.4 MHz, and the pressure set to 20.0 Pa (150 mTorr) is indicated in a graph in FIG. 5B. As is clear from the comparison with the graph in FIG. 5A, it is found that the local increase in etching rate at the center portion of the semiconductor wafer is suppressed according to this embodiment.

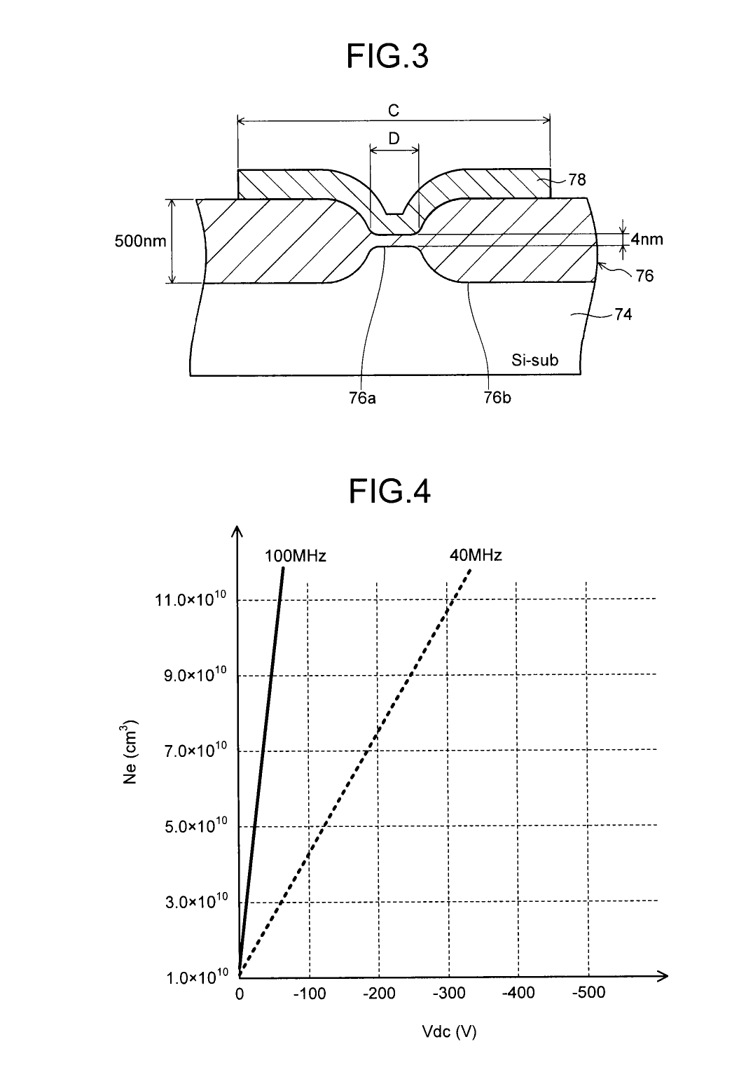

Next, the result of evaluating the state of occurrence of charge-up damage due to plasma using a test wafer will be described. In the evaluation, an element with the structure illustrated in FIG. 3 was used. More specifically, many elements, in each of which a SiO₂ film 76 having a gate oxide film corresponding portion 76a with a thickness of 4 nm and an element isolation region 76b with a thickness of 500 nm was formed on a Si substrate (semiconductor wafer) 74 and a polysilicon film 78 was formed on the SiO₂ film 76, were formed like cells of a matrix on the Si substrate 74. Further, an area C of the polysilicon film 78 was set to be larger than that of a usual element, such as 10000 times (10 k) or 100000 times (100 k) an area D of the gate oxide film corresponding portion 76a, to thereby form a structure in which charge-up damage easily occurred as in the usual stress test. Then, after the elements were exposed to plasma for a certain period of time, the leakage current of each element was measured, and the case where the leakage current was 1×10⁻⁹ A/μm² or more was regarded as occurrence of dielectric breakdown and the case of a value smaller than that was regarded as no dielectric breakdown.

### Example 1

As Example 1, using the plasma etching apparatus 100 illustrated in FIG. 1 and using a Si substrate (semiconductor wafer) with a diameter of 300 mm, the occurrence status of charge-up damage was evaluated under the following plasma etching conditions.

The semiconductor wafer was exposed to plasma under the conditions that
pressure in the processing chamber: 20.0 Pa (150 mTorr)
processing gas: HBr/NF₃/O₂=250/20/10 sccm
first high-frequency: frequency of 100 MHz, power of 500 W
second high-frequency: frequency of 0.4 MHz, power of 1000, 2000, 3000 W
processing time: 10 seconds
gap: 35 mm.

The evaluation results are indicated below. For each case of the second high-frequency power of 1000 W, 2000 W, 3000 W, the result is expressed as a percentage (corresponding to yield) of elements, in which dielectric breakdown has not occurred, to all elements in every 10 k and 100 k.
1000 W: 10 k=100%, 100 k=100%
2000 W: 10 k=100%, 100 k=100%
3000 W: 10 k=100%, 100 k=87%

As Comparative Example 1, similar evaluation was carried out under the same processing conditions as those in Example 1 except that the frequency of the second high-frequency was set to 13 MHz. The evaluation results are indicated below.
1000 W: 10 k=95%, 100 k=49%
2000 W: 10 k=79%, 100 k=49%
3000 W: 10 k=71%, 100 k=57%

As Comparative Example 2, similar evaluation was carried out under the same conditions as those in Example 1 except that the frequency of the second high-frequency was set to 3 MHz. The evaluation results are indicated below.
1000 W: 10 k=88%, 100 k=32%
2000 W: 10 k=58%, 100 k=3%

As described above, in Example 1, dielectric breakdown has not occurred in 100% of elements in the cases of the second high-frequency of 1000 W and 2000 W. Further, in the case of 3000 W, dielectric breakdown has not occurred in 10 k, but dielectric breakdown has occurred in 13% of elements and the percentage of elements in which dielectric breakdown has not occurred (yield) was 87% in 100 k.

In contrast, in Comparative Example 1, dielectric breakdown has occurred in a considerable number of elements, and the dielectric breakdown has occurred in about half of elements, in particular, in the case of 100 k. Further, in Comparative Example 2, dielectric breakdown has occurred in the number of elements equal to or larger than the case of Comparative Example 1.

### Example 2

Next, as Example 2, using the plasma etching apparatus 110 illustrated in FIG. 2 and using a Si substrate (semiconductor wafer) with a diameter of 300 mm, the occurrence status of charge-up damage was evaluated under the following plasma etching conditions. The semiconductor wafer was exposed to plasma under the conditions that
pressure in the processing chamber: 20.0 Pa (150 mTorr)
processing gas: HBr/NF₃/O₂=250/20/10 sccm
first high-frequency: frequency of 100 MHz, power of 500 W
second high-frequency: frequency of 0.4 MHz, power of 2000 W
processing time: 10 seconds
gap: 3 mm.

The evaluation results are indicated below. The result is expressed as a percentage (corresponding to yield) of elements, in which dielectric breakdown has not occurred, to all elements in every 10 k and 100 k.
2000 W: 10 k=100%, 100 k=85%

It is found that in Example 2, the occurrence of charge-up damage is observed in the case of 100 k as compared with Example 1, but the occurrence of charge-up damage is obviously suppressed as compared with Comparative Example 1 and Comparative Example 2.

Further, the etching rate of the oxide film was measured at a plurality of points separate in the diameter direction within the semiconductor wafer in the above-described Example 1, Comparative Example 1, and Comparative Example 2, and their average values and variations were calculated. The average values of the etching rate and their variations were as follows.

### Example 1

1000 W: 33.2 nm/min, ±47.4%

2000 W: 51.4 nm/min, ±124.6%

3000 W: 67.6 nm/min, ±17.7%

### Comparative Example 1

1000 W: 25.4 nm/min, ±144.8%

2000 W: 45.2 nm/min, ±37.3%

3000 W: 67.3 nm/min, ±123.9%

### Comparative Example 2

1000 W: 31.2 nm/min, ±145.2%

2000 W: 60.7 nm/min, ±22.6%

As indicated above, the etching rate and the in-plane uniformity of the etching rate were excellent in Example 1 as compared with Comparative Example 1. On the other hand, substantially the same etching rates and in-plane uniformities of the etching rates were obtained in Comparative Example 2 and Example 1, but the occurrence of dielectric breakdown, namely, the influence by charge-up damage was great as indicated above in Comparative Example 2. It was confirmed that, as described above, the occurrence of charge-up damage could be significantly suppressed and the etching rate and the in-plane uniformity of the etching rate were excellent in Example 1 as compared with Comparative Example 1 and Comparative Example 2.

Next, to investigate the above-described charge-up damage-pressure dependence, using an apparatus with the same structure as that illustrated in FIG. 2 (except that the frequency of the second high-frequency was 13 MHz) and using a Si substrate (semiconductor wafer) with a diameter of 300 mm, the occurrence status of charge-up damage was evaluated under the following plasma etching conditions. The semiconductor wafer was exposed to plasma under the conditions that
pressure in the processing chamber: 3.99 Pa (30 mTorr), 13.3 Pa (100 mTorr), 20.0 Pa (150 mTorr)
processing gas: HBr/NF₃/O₂=250/20/10 sccm
first high-frequency: frequency of 100 MHz, power of 0 W
second high-frequency: frequency of 13 MHz, power of 3000 W
processing time: 10 seconds
gap: 35 mm.

The evaluation results are indicated below. For each case of the pressure in the processing chamber of 3.99 Pa (30 mTorr), 13.3 Pa (100 mTorr), 20.0 Pa (150 mTorr), the result is expressed as a percentage (corresponding to yield) of elements, in which dielectric breakdown has not occurred, to all elements in every 10 k and 100 k.
pressure of 3.99 Pa (30 mTorr): 10 k=100%, 100 k=100%
pressure of 13.3 Pa (100 mTorr): 10 k=90%, 100 k=68%
pressure of 20.0 Pa (150 mTorr): 10 k=67%, 100 k=48%

As indicated in the above evaluation results, it was found that when the pressure in the processing chamber was a high pressure of 13.3 Pa (100 mTorr) or higher, the charge-up damage significantly appeared.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A plasma etching method of etching a silicon layer of a substrate to be processed, comprising:
preparing a plasma etching apparatus, the plasma etching apparatus comprising: a processing chamber configured to house the substrate to be processed; a lower electrode arranged in the processing chamber, configured to mount the substrate to be processed thereon; an upper electrode arranged in the processing chamber, the upper electrode being opposed to the lower electrode; an etching gas supply mechanism configured to supply a predetermined etching gas into the processing chamber; and an exhaust mechanism configured to exhaust gas from the processing chamber;
forming an atmosphere at a pressure of 13.3 Pa or more in the processing chamber by at least one of the etching gas supply mechanism and the exhaust mechanism; and
applying, to the lower electrode, a first high-frequency power with a first frequency and a second high-frequency power with a second frequency being lower than the first frequency, the second frequency being a frequency of 1 MHz or lower.

2. The plasma etching method according to claim 1,
wherein the first frequency is 80 MHz or higher and 150 MHz or lower.

3. The plasma etching method according to claim 1,
wherein the etching gas contains gas containing a halogen element.

4. The plasma etching method according to claim 2,
wherein the etching gas contains gas containing a halogen element.

5. A plasma etching apparatus for etching a silicon layer of a substrate to be processed, comprising:
a processing chamber configured to house the substrate to be processed;
a lower electrode arranged in the processing chamber, configured to mount the substrate to be processed thereon;
an upper electrode arranged in the processing chamber, and the upper electrode being opposed to the lower electrode;
an etching gas supply mechanism configured to supply a predetermined etching gas into the processing chamber;
an exhaust mechanism configured to exhaust gas from the processing chamber;
a first high-frequency power supply configured to apply a first high-frequency power with a frequency of 80 MHz or higher and 150 MHz or lower to the lower electrode; and
a second high-frequency power supply configured to apply a second high-frequency power with a frequency of 1 MHz or lower to the lower electrode.

6. The plasma etching apparatus according to claim 5,
wherein a quartz member is arranged on a surface, of the upper electrode, opposed to the lower electrode.

7. The plasma etching apparatus according to claim 5,
wherein the upper electrode is vertically movable to change a gap between the upper electrode and the lower electrode.

8. The plasma etching apparatus according to claim 6,
wherein the upper electrode is vertically movable to change a gap between the upper electrode and the lower electrode.
